(19) United States
(12) Patent Application Publication
(10) Pub. No.: US 2026/0353891 A1
(43) Pub. Date: Nov. 5, 2026

(54) DISPLAY PANEL AND DISPLAY DEVICE

(71) Applicant: TIANMA ADVANCED DISPLAY TECHNOLOGY INSTITUTE (XIAMEN) CO., LTD., Xiamen (CN)

(72) Inventors: Wang CHEN, Xiamen (CN); Yingteng ZHAI, Xiamen (CN); Yuqi HU, Xiamen (CN)

(21) Appl. No.: 19/715,452

(22) Filed: Jun. 22, 2026

(30) Foreign Application Priority Data
Mar. 5, 2026 (CN) 202610265698.2

(51) Int. Cl. H10H 29/49; G09G 3/32

(52) U.S. Cl. CPC H10H 29/49; G09G 3/32; G09G 2300/0426; G09G 2300/0819; G09G 2300/0852; G09G 2300/0861; G09G 2320/0233; G09G 2330/02

(57) ABSTRACT

Provided are a display panel and a display device. The display panel includes: a substrate; a circuit layer including pixel circuits including a first pixel circuit and a second pixel circuit, one of the pixel circuits includes a driving transistor and a first conductive portion, the first conductive portion including a gate of the driving transistor, and/or at least part of the first conductive portion being electrically connected to the gate of the driving transistor; a first metal portion including first vent holes; a second metal portion including a second electrode and a first electrode; and a light emitting element. In the first pixel circuit, the first conductive portion includes a first sub-portion overlapping with the first electrode and the first metal portion and not overlapping with the first vent holes; and/or in the second pixel circuit, the first conductive portion does not overlap with the first electrode.

### CROSS-REFERENCE TO RELATED APPLICATIONS

The present application claims priority to Chinese Patent Application No. 202610265698.2, filed on Mar. 5, 2026, the content of which is incorporated herein by reference in its entirety.

### TECHNICAL FIELD

The present disclosure relates to the field of display technologies, and in particular, to a display panel and a display device.

### BACKGROUND

A display panel includes a pixel circuit and a light emitting element. A driving transistor in the pixel circuit is a core device, and an operation state thereof directly affects a magnitude of a driving current output by the pixel circuit to the light emitting element, thereby affecting the light emitting precision of the light emitting element.

However, in an actual product, a gate potential of the driving transistor is extremely prone to being unstable due to interference from other signals, further causing fluctuation of the driving current, as a result, the display panel has undesirable problems such as display non-uniformity.

### SUMMARY

Embodiments of the present disclosure provide a display panel and a display device for improving the stability of the gate potential of the driving transistor in the pixel circuit, and further improving the display effect.

In a first aspect, an embodiment of the present disclosure provides a display panel, including: a substrate; a circuit layer located on a side of the substrate, the circuit layer including pixel circuits including a first pixel circuit and a second pixel circuit, one pixel circuit of the pixel circuits includes a driving transistor and a first conductive portion; the first conductive portion including a first portion, and the first portion being a gate of the driving transistor; and/or the first conductive portion including a second portion, and the second portion being electrically connected to the gate of the driving transistor; a first metal portion located on a side of the circuit layer away from the substrate, the first metal portion including first vent holes; a second metal portion located on a side of the first metal portion away from the substrate, the second metal portion including a first electrode and a second electrode, and the first electrode being electrically connected to the pixel circuit; and a light emitting element located on a side of the second metal portion away from the substrate, the light emitting element being electrically connected to the first electrode and the second electrode.

In the first pixel circuit, the first conductive portion includes a first sub-portion; and in a direction perpendicular to a plane of the substrate, the first sub-portion overlaps with the first electrode, and the first sub-portion overlaps with the first metal portion and does not overlap with the first vent holes, and/or in the direction perpendicular to the plane of the substrate, the first conductive portion in the second pixel circuit does not overlap with the first electrode.

In a second aspect, based on the same inventive concept, an embodiment of the present disclosure further provides a display device including a display panel, including: a substrate; a circuit layer located on a side of the substrate, the circuit layer including pixel circuits including a first pixel circuit and a second pixel circuit, one pixel circuit of the pixel circuits includes a driving transistor and a first conductive portion; the first conductive portion including a first portion, and the first portion being a gate of the driving transistor; and/or the first conductive portion including a second portion, and the second portion being electrically connected to the gate of the driving transistor; a first metal portion located on a side of the circuit layer away from the substrate, the first metal portion including first vent holes; a second metal portion located on a side of the first metal portion away from the substrate, the second metal portion including a first electrode and a second electrode, and the first electrode being electrically connected to the pixel circuit; and a light emitting element located on a side of the second metal portion away from the substrate, the light emitting element being electrically connected to the first electrode and the second electrode.

In the first pixel circuit, the first conductive portion includes a first sub-portion; and in a direction perpendicular to a plane of the substrate, the first sub-portion overlaps with the first electrode, and the first sub-portion overlaps with the first metal portion and does not overlap with the first vent holes, and/or in the direction perpendicular to the plane of the substrate, the first conductive portion in the second pixel circuit does not overlap with the first electrode.

### BRIEF DESCRIPTION OF DRAWINGS

For the purpose of better explaining the technical solutions in the embodiments of the present disclosure or in the related art, the drawings required to be used for the description of the embodiments or the related art will be briefly introduced below. Apparently, the drawings in the following description are some embodiments of the present disclosure, and those of skill in the art can obtain other drawings from these drawings without creative efforts.

FIG. 1 is a schematic diagram of a display panel according to an embodiment of the present disclosure;

FIG. 2 is another schematic diagram of a display panel according to an embodiment of the present disclosure;

FIG. 3 is a schematic diagram of a pixel circuit according to an embodiment of the present disclosure;

FIG. 4 is a schematic diagram of a first metal portion in FIG. 1;

FIG. 5 is a schematic diagram of a second metal portion in FIG. 1;

FIG. 6 is a schematic diagram of a region K in FIG. 1;

FIG. 7 is another schematic diagram of a display panel according to an embodiment of the present disclosure;

FIG. 8 is a cross-sectional view along A1-A2 in FIG. 7;

FIG. 9 is another schematic diagram of a display panel according to an embodiment of the present disclosure;

FIG. 10 is another schematic diagram of a pixel circuit according to an embodiment of the present disclosure;

FIG. 11 is another schematic diagram of a pixel circuit according to an embodiment of the present disclosure;

FIG. 12 is another schematic diagram of a pixel circuit according to an embodiment of the present disclosure;

FIG. 13 is another schematic diagram of a display panel according to an embodiment of the present disclosure;

FIG. 14 is another schematic diagram of a display panel according to an embodiment of the present disclosure;

FIG. 15 is a cross-sectional view along B1-B2 in FIG. 14;

FIG. 16 is another schematic diagram of a display panel according to an embodiment of the present disclosure;

FIG. 17 is a schematic diagram of distances among a first hole, a second hole, and a third hole according to an embodiment of the present disclosure;

FIG. 18 is a schematic diagram of a distribution of first vent holes according to an embodiment of the present disclosure;

FIG. 19 is a schematic diagram of another distribution of first vent holes according to an embodiment of the present disclosure;

FIG. 20 is another schematic diagram of a display panel according to an embodiment of the present disclosure;

FIG. 21 is another schematic diagram of a display panel according to an embodiment of the present disclosure;

FIG. 22 is another schematic diagram of a display panel according to an embodiment of the present disclosure;

FIG. 23 is another schematic diagram of a display panel according to an embodiment of the present disclosure;

FIG. 24 is another schematic diagram of a display panel according to an embodiment of the present disclosure;

FIG. 25 is another schematic diagram of a display panel according to an embodiment of the present disclosure;

FIG. 26 is another schematic diagram of a display panel according to an embodiment of the present disclosure;

FIG. 27 is another schematic diagram of a display panel according to an embodiment of the present disclosure;

FIG. 28 is another schematic diagram of a display panel according to an embodiment of the present disclosure;

FIG. 29 is another schematic diagram of a display panel according to an embodiment of the present disclosure;

FIG. 30 is a schematic diagram of a region A in FIG. 29;

FIG. 31 is another schematic diagram of a display panel according to an embodiment of the present disclosure;

FIG. 32 is a schematic diagram of a region B in FIG. 29;

FIG. 33 is another schematic diagram of a display panel according to an embodiment of the present disclosure;

FIG. 34 is a schematic diagram of a region C in FIG. 29;

FIG. 35 is a schematic diagram of a display device according to an embodiment of the present disclosure; and

FIG. 36 is another schematic diagram of a display device according to an embodiment of the present disclosure.

### DESCRIPTION OF EMBODIMENTS

In order to better illustrate technical solutions of the present disclosure, embodiments of the present disclosure are described in detail below in conjunction with the drawings.

It should be clear that the described embodiments are merely part of the embodiments of the present disclosure rather than all of the embodiments. All other embodiments obtained by those skilled in the art without creative efforts according to the embodiments of the present disclosure should fall within the protection scope of the present disclosure.

Terms used in the embodiments of the present disclosure are merely for the purpose of describing specific embodiments, but not intended to limit the present disclosure. Singular forms of “a/an”, “said” and “the” used in the embodiments of the present disclosure and the appended claims are also intended to include plural forms, unless the context clearly indicates otherwise.

It should be understood that the term “and/or” used herein is merely an association relationship describing an associated object, indicating that there may be three relationships, for example, A and/or B, and may indicate: only A, both A and B, and only B. In addition, the character “/” herein generally indicates that the related objects before and after the character present an “or” relationship.

An embodiment of the present disclosure provides a display panel. The display panel may be a light emitting diode (LED) display panel, such as a mini LED display panel or a micro LED display panel.

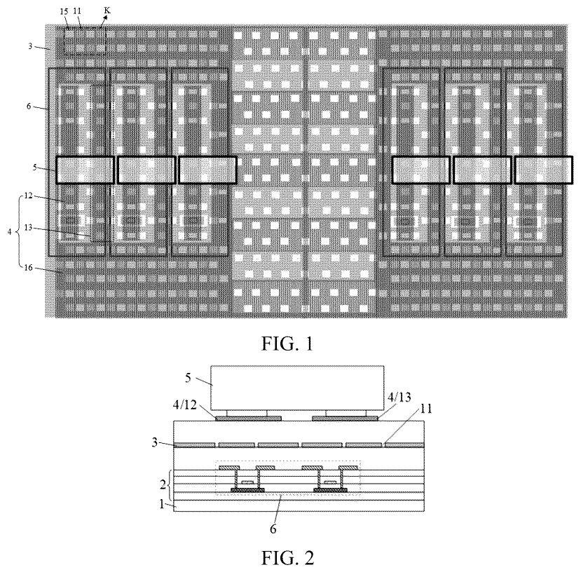

FIG. 1 is a schematic diagram of a display panel according to an embodiment of the present disclosure, and FIG. 2 is another schematic diagram of a display panel according to an embodiment of the present disclosure. As shown in FIG. 1 and FIG. 2, the display panel includes a substrate 1, a circuit layer 2 located on a side of the substrate 1, a first metal portion 3 located on a side of the circuit layer 2 away from the substrate 1, a second metal portion 4 located on a side of the first metal portion 3 away from the substrate 1, and a light emitting element 5 located on a side of the second metal portion 4 away from the substrate 1.

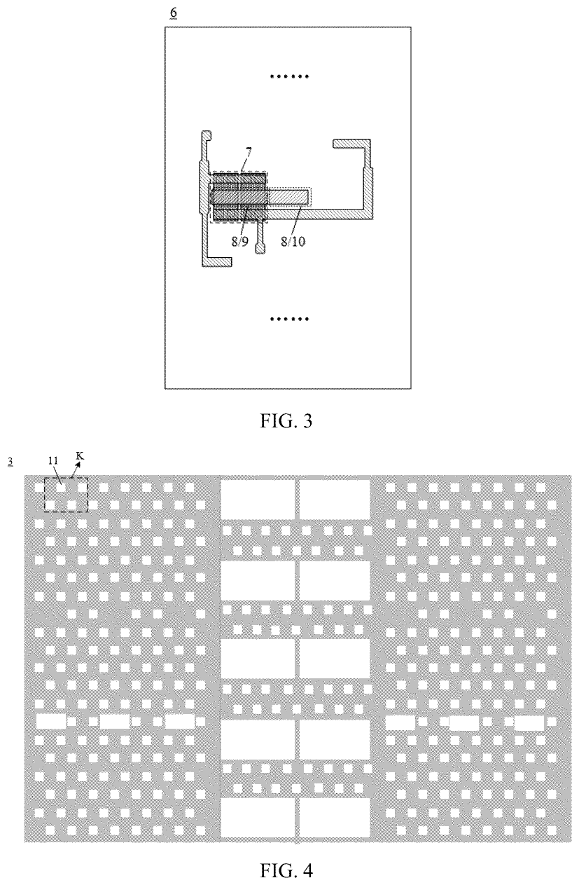

The circuit layer 2 includes a pixel circuit 6. FIG. 3 is a schematic diagram of a pixel circuit according to an embodiment of the present disclosure. As shown in FIG. 3, the pixel circuit 6 includes a driving transistor 7. The pixel circuit 6 further includes a first conductive portion 8. The first conductive portion 8 includes a first portion 9, and the first portion 9 is a gate of the driving transistor 7, and/or the first conductive portion 8 includes a second portion 10, and the second portion 10 is electrically connected to a gate of the driving transistor 7. The second portion 10 may be directly connected or indirectly connected to the gate of the driving transistor 7, and a signal transmitted on the second portion 10 is the same as a signal transmitted on the gate of the driving transistor 7.

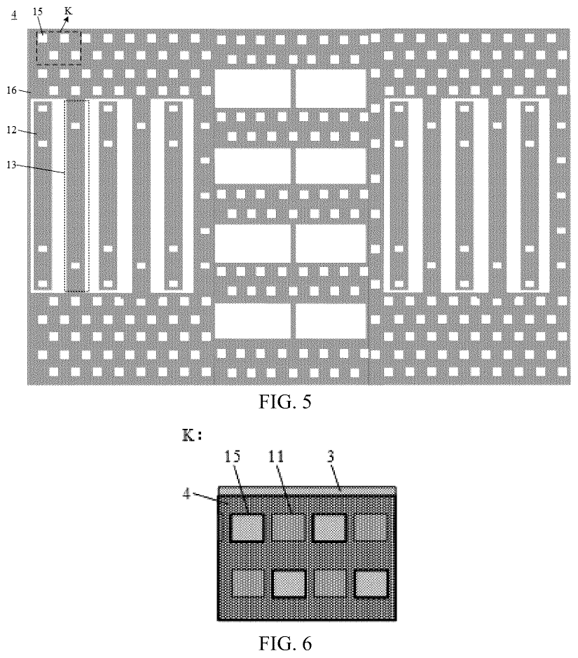

FIG. 4 is a schematic diagram of the first metal portion in FIG. 1, and FIG. 5 is a schematic diagram of the second metal portion in FIG. 1. With reference to FIG. 1, FIG. 4, and FIG. 5, the first metal portion 3 includes first vent holes 11. The first vent holes 11 are configured to discharge gas generated in the manufacturing process of a lower film layer, so as to prevent film layer separation caused by gas accumulation. In an embodiment of the present disclosure, the first metal portion 3 may transmit a constant voltage signal. For example, the first metal portion 3 is configured to transmit a power signal, and may be a planar structure. The second metal portion 4 includes a first electrode 12 and a second electrode 13. The first electrode 12 is respectively electrically connected to the light emitting element 5 and the pixel circuit 6, and is configured to transmit a driving signal generated by the pixel circuit 6 to a first terminal of the light emitting element 5. The second electrode 13 is respectively electrically connected to the light emitting element 5 and the cathode wiring 16. The cathode wiring 16 may be located at the second metal portion 4 and communicate with the second electrode 13 to form an integrated structure. The second electrode 13 is configured to transmit a cathode signal of the cathode wiring 16 to the second terminal of the light emitting element 5, so that the light emitting element 5 emits light under the action of a voltage difference between the first terminal and the second terminal. That is, the first electrode 12 is electrically connected to the pixel circuit 6, the second electrode 13 is electrically connected to the cathode wiring 16, and the light emitting element 5 is respectively electrically connected to the first electrode 12 and the second electrode 13.

In addition, the second metal portion 4 may also include second vent holes 15. Similarly to the first vent holes 11, the second vent holes 15 are also configured to discharge gas generated in the manufacturing process of a lower film layer, so as to prevent film layer separation caused by gas accumulation. In conjunction with FIG. 1 and FIG. 4 to FIG. 6, where FIG. 6 is a schematic diagram of a region K in FIG. 1, in at least some positions, the second vent holes 15 and the first vent holes 11 may be staggered from each other. That is, in a direction perpendicular to a plane of the substrate 1, the second vent hole 15 does not overlap with the first vent hole 11.

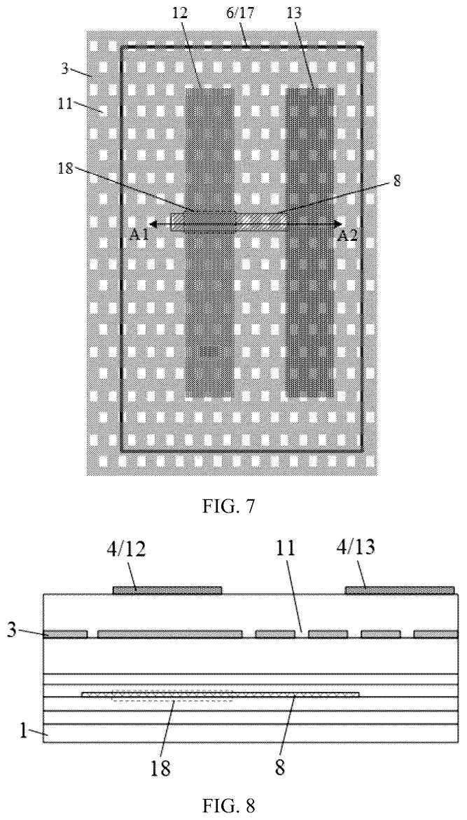

FIG. 7 is another schematic diagram of a display panel according to an embodiment of the present disclosure, and FIG. 8 is a cross-sectional view along A1-A2 in FIG. 7. As shown in FIG. 7 and FIG. 8, the pixel circuit 6 includes a first pixel circuit 17, and the first conductive portion 8 in the first pixel circuit 17 includes a first sub-portion 18. The first sub-portion 18 overlaps with the first electrode 12 in the direction perpendicular to the plane of the substrate 1. In other words, the first sub-portion 18 is a portion of the first conductive portion 8 that overlaps with the first electrode 12. Further, the first sub-portion 18 overlaps with the first metal portion 3 and does not overlap with the first vent hole 11, that is, the first sub-portion 18 is covered by metal in the first metal portion 3.

Regarding the first sub-portion 18, in conjunction with FIG. 3, in a same first pixel circuit 17, according to the overlapping situation between the first pixel circuit 17 and the first electrode 12, the first sub-portion 18 may include at least part of the first portion 9 or at least part of the second portion 10. In addition, the overlapping situations between the first pixel circuits 17 and the first electrodes 12 may be the same at different positions or may vary at different positions. For example, when overlapping situations between at least some of the first pixel circuits 17 and the first electrodes 12 are the same, patterns of the first sub-portions 18 in these first pixel circuits 17 are the same. When overlapping situations between at least some of the first pixel circuits 17 and the first electrodes 12 are different, patterns of the first sub-portions 18 in these first pixel circuits 17 are different. However, regardless of the pattern of the first sub-portion 18, the first sub-portion 18 in the respective first pixel circuit 17 overlaps with the first metal portion 3 and does not overlap with the first vent hole 11.

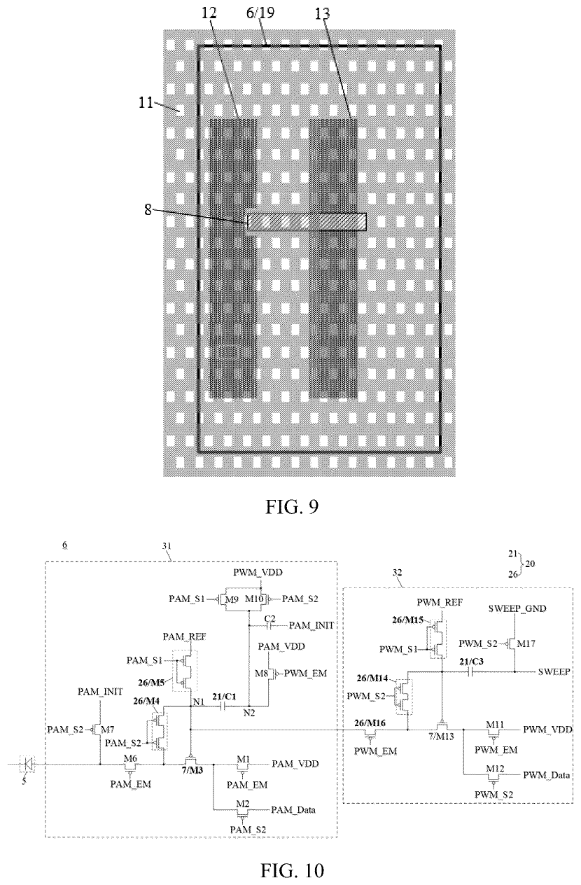

Additionally/alternatively, FIG. 9 is another schematic diagram of a display panel according to an embodiment of the present disclosure. As shown in FIG. 9, the pixel circuit 6 includes a second pixel circuit 19. In the direction perpendicular to the plane of the substrate 1, the first conductive portion 8 in the second pixel circuit 19 does not overlap with the first electrode 12. Further, in the direction perpendicular to the plane of the substrate 1, the second pixel circuit 19 overlaps with the first electrode 12, but the first conductive portion 8 in the second pixel circuit 19 does not overlap with the first electrode 12.

The first electrode 12 is configured to transmit the driving signal provided by the pixel circuit 6 to the light emitting element 5. During the display process, the driving signal frequently jumps abruptly. In the related art, the first electrode overlaps with a structure that transmits a gate potential of the driving transistor in the pixel circuit, and relatively large coupling exists between the first electrode and the structure. When the driving signal jumps, interference is generated to the gate potential of the driving transistor, thereby affecting the stability of the gate potential of the driving transistor.

In view of this, the embodiments of the present disclosure provide that, in at least some of the pixel circuits 6, that is, in the first pixel circuit 17, when designing the first vent holes 11 of the first metal portion 3 at this position, the first vent holes 11 at the position of the first sub-portion 18 may be removed or moved away, so that the first vent holes 11 avoid the first sub-portion 18. Further, the metal of the first metal portion 3 is spaced in a directly facing region between the first sub-portion 18 and the first electrode 12, and this part of the metal serves as a shielding electrode, which may shield the influence of the jump of the driving signal on the first electrode 12 on the signal on the first sub-portion 18, thereby reducing or eliminating the influence on the gate potential of the driving transistor 7 in the first pixel circuit 17.

Additionally/alternatively, in at least some of the pixel circuits 6, that is, in the second pixel circuit 19, in the embodiments of the present disclosure, the shape, position, and the like of the first electrode 12 at the position of the second pixel circuit 19 may be adjusted, so that the first electrode 12 and the first conductive portion 8 in the second pixel circuit 19 avoid each other and do not overlap with each other, thereby reducing or eliminating the coupling between the first electrode 12 and the first conductive portion 8, so as to reduce or eliminate the interference of the jump of the driving signal on the first electrode 12 to the signal on the first conductive portion 8, and to reduce or eliminate the influence on the gate potential of the driving transistor 7 in the second pixel circuit 19.

By adopting the technical solution according to the embodiments of the present disclosure, the influence of the jump of the driving signal on the first electrode 12 on the gate potential of the driving transistor 7 in the pixel circuit 6 can be reduced or eliminated, and the stability of the gate potential of the driving transistor 7 can be improved. Especially in a case that the coupling degrees between the first conductive portions 8 and the first electrodes 12 in the pixel circuits 6 are inconsistent at different positions, this solution can effectively eliminate the coupling difference between the first conductive portions 8 and the first electrodes 12 in different pixel circuits 6, thereby effectively improving the display uniformity, etc.

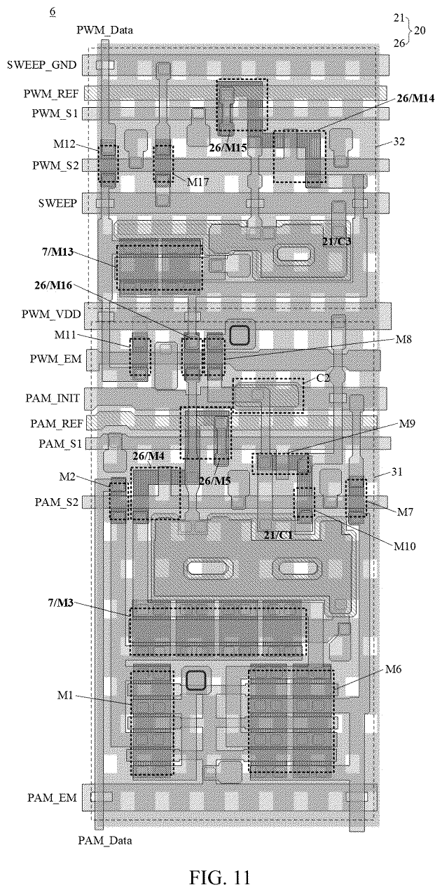

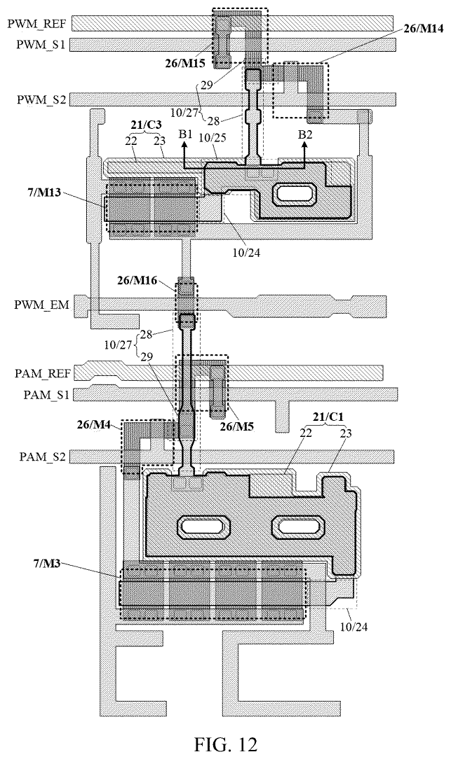

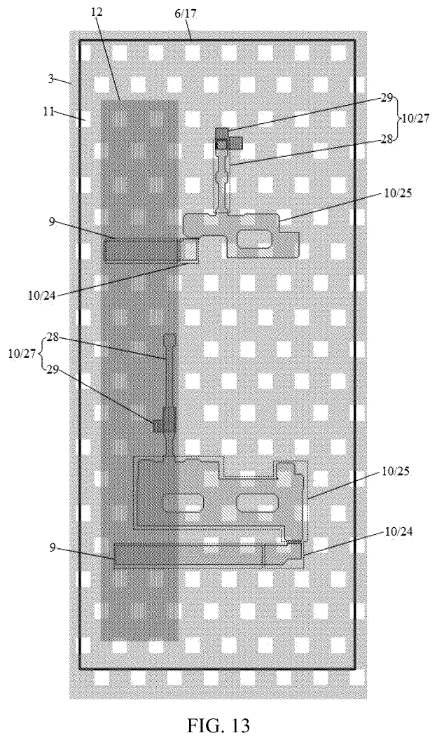

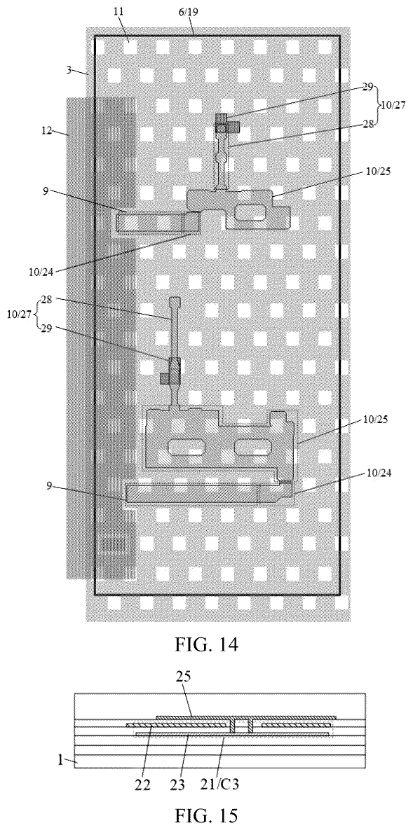

FIG. 10 is another schematic diagram of a pixel circuit according to an embodiment of the present disclosure. FIG. 11 is another schematic diagram of a pixel circuit according to an embodiment of the present disclosure. FIG. 12 is another schematic diagram of a pixel circuit according to an embodiment of the present disclosure. FIG. 13 is another schematic diagram of a display panel according to an embodiment of the present disclosure. FIG. 14 is another schematic diagram of a display panel according to an embodiment of the present disclosure. In a feasible implementation, as shown in FIG. 10 to FIG. 14, the pixel circuit 6 further includes a preset module 20. The preset module 20 is electrically connected to the gate of the driving transistor 7, and the second portion 10 is further electrically connected to the preset module 20.

For the first pixel circuit 17, when at least part of the second portion 10 serves as the first sub-portion 18, this part of the second portion 10 overlaps with the first metal portion 3 and does not overlap with the first vent holes 11, which can reduce or eliminate the influence of the signal on the first electrode 12 on the signal on this part of the second portion 10, thereby improving the potential stability of the gate of the driving transistor 7 and the preset module 20 connected thereto. For the second pixel circuit 19, the second portion 10 in the second pixel circuit 19 avoids the first electrode 12, which can also reduce or eliminate the influence of the signal on the first electrode 12 on the signal on the second portion 10, thereby improving the potential stability of the gate of the driving transistor 7 and the preset module 20 connected thereto.

The second portion 10 being further electrically connected to the preset module 20 at least includes that: at least part of the second portion 10 is connected to the gate of the driving transistor 7, and/or at least part of the second portion 10 is connected to the preset module 20, and/or at least part of the second portion 10 is connected between the gate of the driving transistor 7 and the preset module 20.

Further, with reference to FIG. 10 to FIG. 14, the preset module 20 includes a first capacitor 21. The first capacitor 21 includes a first electrode plate 22 and a second electrode plate 23, and the first electrode plate 22 is electrically connected to the gate of the driving transistor 7. The second portion 10 includes a first wiring 24 connected between the gate of the driving transistor 7 and the first electrode plate 22. The first electrode plate 22, the first wiring 24 and the gate of the driving transistor 7 may be arranged in the same layer.

Additionally/alternatively, FIG. 15 is a cross-sectional view along B1-B2 in FIG. 14. With reference to FIG. 10 to FIG. 15, the preset module 20 includes a first capacitor 21. The first capacitor 21 includes a first electrode plate 22 and a second electrode plate 23, and the first electrode plate 22 is electrically connected to the gate of the driving transistor 7. The second portion 10 includes an auxiliary electrode plate 25 that is located on a side of the first capacitor 21 away from the substrate 1. In the direction perpendicular to the plane of the substrate 1, the auxiliary electrode plate 25 overlaps with the first capacitor 21, and the auxiliary electrode plate 25 is electrically connected to the first electrode plate 22.

An auxiliary electrode plate 25 connected to the first electrode plate 22 is further provided above the second electrode plate 23, and a capacitor is also formed between the auxiliary electrode plate 25 and the second electrode plate 23. The capacitor and the first capacitor 21 form a parallel capacitor structure, which can be used to increase the capacitance value under the condition that the electrode plate occupies a certain area.

Additionally/alternatively, the preset module 20 includes a first transistor 26 electrically connected to the gate of the driving transistor 7. The second portion 10 includes a second wiring 27 connected between the gate of the driving transistor 7 and the first transistor 26.

In the embodiments of the present disclosure, the second line segment 29 may be indirectly electrically connected to the gate of the driving transistor 7 through the auxiliary electrode plate 25 and the first electrode plate 22. The second wiring 27 may include a first line segment 28 and/or a second line segment 29. The first line segment 28 is in a same layer as and connected to the auxiliary electrode plate 25, and the second line segment 29 is in a same layer as and connected to an active layer of the first transistor 26. The active layer of the first transistor 26 includes a channel region and two doped regions. The two doped regions are respectively N-type heavily doped and P-type heavily doped. The two doped regions are located on two sides of the channel region and are both directly connected to the channel region. The second line segment 29 is a connection wiring between devices. The doping degree in the second line segment 29 may be less than the doping degree of the doped regions, and a boundary therebetween may be determined according to a position at which a difference in terms of doping degree occurs.

The first wiring 24, the auxiliary electrode plate 25 and/or the second wiring 27 are directly or indirectly connected to the gate of the driving transistor 7. For this part of the structure, by adopting a manner in which the first vent holes 11 avoid as shown in FIG. 13 or a manner in which the first electrode 12 avoids as shown in FIG. 14, the influence of the jump of the signal on the first electrode 12 on the signal transmitted on this part of the structure can be shielded or avoided, thereby reducing or eliminating the influence on the gate potential of the driving transistor 7.

The first capacitor 21 and the first transistor 26 are specifically illustrated below by taking the circuit shown in FIG. 10 as an example.

The pixel circuit 6 includes a pulse amplitude modulation circuit 31 and a pulse width modulation circuit 32.

The pulse amplitude modulation circuit 31 includes a first sub-capacitor C1, a second sub-capacitor C2, a first driving transistor M3, a first data writing transistor M2, a first threshold compensation transistor M4, a first reset transistor M7, a second reset transistor M5, a first light emitting control transistor M1, a second light emitting control transistor M6, a first control transistor M8, a second control transistor M9, and a third control transistor M10.

A gate of the first driving transistor M3 is electrically connected to a first node N1.

The first data writing transistor M2 includes a gate electrically connected to a first scan line PAM_S2, a first terminal electrically connected to a first data line PAM_Data, and a second terminal electrically connected to a first terminal of the first driving transistor M3.

The first threshold compensation transistor M4 includes a gate electrically connected to the first scan line PAM_S2, a first terminal electrically connected to a second terminal of the first driving transistor M3, and a second terminal electrically connected to a gate of the first driving transistor M3.

The first reset transistor M7 includes a gate electrically connected to the first scan line PAM_S2, a first terminal electrically connected to a first reset line PAM_INIT, and a second terminal electrically connected to the light emitting element 5.

The second reset transistor M5 includes a gate electrically connected to a second scan line PAM_S1, a first terminal electrically connected to a second reset line PAM_REF, and a second terminal electrically connected to the gate of the first driving transistor M3.

The first light emitting control transistor M1 includes a gate electrically connected to a second light emitting control line PAM_EM, a first terminal receiving a first power signal PAM_VDD, and a second terminal electrically connected to the first terminal of the first driving transistor M3.

The second light emitting control transistor M6 includes a gate electrically connected to the second light emitting control line PAM_EM, a first terminal electrically connected to the second terminal of the first driving transistor M3, and a second terminal electrically connected to the light emitting element 5.

The first sub-capacitor C1 includes a first electrode plate electrically connected to the first node N1, and a second electrode plate electrically connected to a second node N2.

The second sub-capacitor C2 includes a first electrode plate electrically connected to the second node N2, and a second electrode plate electrically connected to the first reset line PAM_INIT.

The first control transistor M8 includes a gate electrically connected to the first light emitting control line PWM_EM, a first terminal receiving the first power signal PAM_VDD, and a second terminal electrically connected to the second node N2.

The second control transistor M9 includes a gate electrically connected to the second scan line PAM_S1, a first terminal receiving the second power signal PWM_VDD, and a second terminal electrically connected to the second node N2.

The third control transistor M10 includes a gate electrically connected to the first scan line PAM_S2, a first terminal receiving the second power signal PWM_VDD, and a second terminal electrically connected to the second node N2.

The pulse width modulation circuit 32 includes a second driving transistor M13, a second data writing transistor M12, a second threshold compensation transistor M14, a third reset transistor M15, a fourth reset transistor M17, a third light emitting control transistor M11, a fourth light emitting control transistor M16, and a third sub-capacitor C3.

The third sub-capacitor C3 includes a first electrode plate electrically connected to the gate of the second driving transistor M13, and a second electrode plate electrically connected to a swept-frequency signal line SWEEP.

The second data writing transistor M12 includes a gate electrically connected to the third scan line PWM_S2, a first terminal electrically connected to the second data line PWM-Data, and a second terminal electrically connected to the first terminal of the second driving transistor M13.

The second threshold compensation transistor M14 includes a gate electrically connected to a third scan line PWM_S2, a first terminal electrically connected to the second terminal of the second driving transistor M13, and a second terminal electrically connected to the gate of the second driving transistor M13.

The third reset transistor M15 includes a gate electrically connected to a fourth scan line PWM_S1, a first terminal electrically connected to the third reset line PWM_REF, and a second terminal electrically connected to the gate of the second driving transistor M13.

The third light emitting control transistor M11 includes a gate electrically connected to the first light emitting control line PWM_EM, a first terminal receiving the second power signal PWM_VDD, and a second terminal electrically connected to the first terminal of the second driving transistor M13.

The fourth light emitting control transistor M16 includes a gate electrically connected to the first light emitting control line PWM_EM, a first terminal electrically connected to the second terminal of the second driving transistor M13, and a second terminal electrically connected to the first node N1.

In the embodiments of the present disclosure, the first metal portion 3 may be configured to transmit the first power signal PAM_VDD and/or the second power signal PWM_VDD.

For example, at least part of the first metal portion 3 transmits the first power signal PAM_VDD, and this part of the first metal portion 3 is electrically connected to the first terminal of the first light emitting control transistor M1 and the first terminal of the first control transistor M8. At least part of the first metal portion 3 transmits the second power signal PWM_VDD, and this part of the first metal portion 3 is electrically connected to the first terminal of the second control transistor M9, the first terminal of the third control transistor M10, and the first terminal of the third light emitting control transistor M11.

For example, in the structure shown in FIG. 11, the first metal portion 3 is configured to transmit the first power signal PAM_VDD. The first terminal of the first light emitting control transistor M1 and the first terminal of the first control transistor M8 are electrically connected to the first metal portion 3. The first terminal of the second control transistor M9, the first terminal of the third control transistor M10 and the first terminal of the third light emitting control transistor M11 are electrically connected to the second power line PWM_VDD. The second power line PWM_VDD is configured to transmit the second power signal.

In the embodiments of the present disclosure, the driving transistor 7 includes a first driving transistor M3 and/or a second driving transistor M13.

When the driving transistor 7 includes the first driving transistor M3, the first capacitor 21 includes the first sub-capacitor C1, and the first transistor 26 includes the first threshold compensation transistor M4 and the second reset transistor M5.

When the driving transistor 7 includes the second driving transistor M13, the first capacitor 21 includes a third sub-capacitor C3, and the first transistor 26 includes a fourth light emitting control transistor M16, a second threshold compensation transistor M14, and a third reset transistor M15.

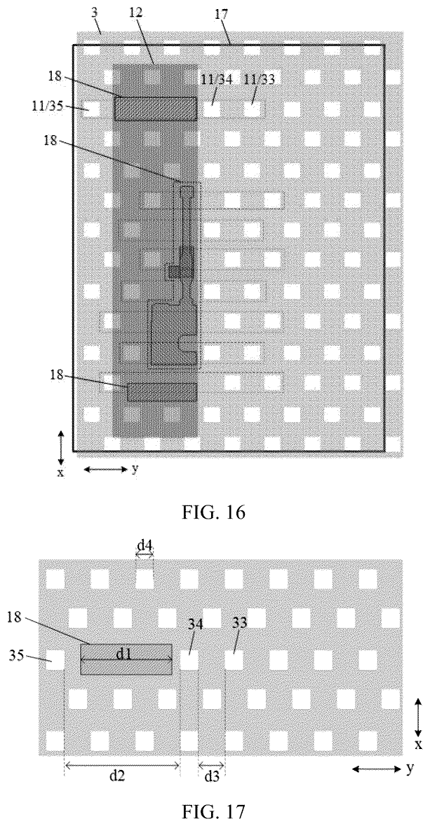

FIG. 16 is another schematic diagram of a display panel according to an embodiment of the present disclosure. FIG. 17 is a schematic diagram of distances among a first hole, a second hole, and a third hole according to an embodiment of the present disclosure. In a feasible implementation, as shown in FIG. 16 and FIG. 17, the first vent holes 11 include a first hole 33, a second hole 34, and a third hole 35 that are arranged in the same direction and are adjacent to each other. That is, along the arrangement direction of the three, the first hole 33 is adjacent to the second hole 34, and the second hole 34 is adjacent to the third hole 35.

FIG. 16 is schematic illustration taking that the first hole 33, the second hole 34, and the third hole 35 are provided in the second direction y as an example. The first hole 33, the second hole 34, and the third hole 35 may also be provided in the first direction x intersecting with the second direction y.

In the direction perpendicular to the plane of the substrate 1, the first hole 33, the second hole 34 and the third hole 35 overlap with the same first pixel circuit 17. With reference to FIG. 17, in the direction perpendicular to the plane of the substrate 1, the first metal portion 3 between the second hole 34 and the third hole 35 overlaps with the first sub-portion 18, and the minimum distance d2 between the second hole 34 and the third hole 35 is greater than the minimum distance d3 between the second hole 34 and the first hole 33.

In an embodiment, at least one first vent hole 11 should originally be arranged between the second hole 34 and the third hole 35. In the embodiments of the present disclosure, the first vent hole 11 that should originally be arranged between the second hole 34 and the third hole 35 is removed, so that the distance between the second hole 34 and the third hole 35 is increased to be greater than the distance between the first hole 33 and the second hole 34, thereby causing the first sub-portion 18 not to overlap with the first vent hole 11.

In an embodiment, along the arrangement direction of the first hole 33, the second hole 34, and the third hole 35, a width of the first vent hole 11 is d4, and d2≥m×d4+(m+1)×d3, where m≥1, and m may also be understood as the number of first vent holes 11 that should be originally arranged between the second hole 34 and the third hole 35.

Alternatively, in another embodiment of the present disclosure, the second hole 34 and the third hole 35 may also respectively be moved in a direction away from each other, so that the distance between the second hole 34 and the third hole 35 is increased to be greater than the distance between the first hole 33 and the second hole 34, thereby causing the first sub-portion 18 not to overlap with the first vent hole 11.

In a feasible implementation, referring to FIG. 17 again, the length of the first sub-portion 18 in the arrangement direction of the second hole 34 and the third hole 35 is d1, and the minimum distance between the second hole 34 and the third hole 35 is d2, where d2≥d1, so that the first sub-portion 18 is entirely covered by metal of the first metal portion 3.

Further, d1 is the maximum length of the first sub-portion 18 in the arrangement direction of the second hole 34 and the third hole 35, and d2>d1. In this way, a certain margin may be reserved for the positional deviation of the first sub-portion 18 and/or the first vent hole 11, so as to prevent the first sub-portion 18 from overlapping with the first vent hole 11 to a greater extent.

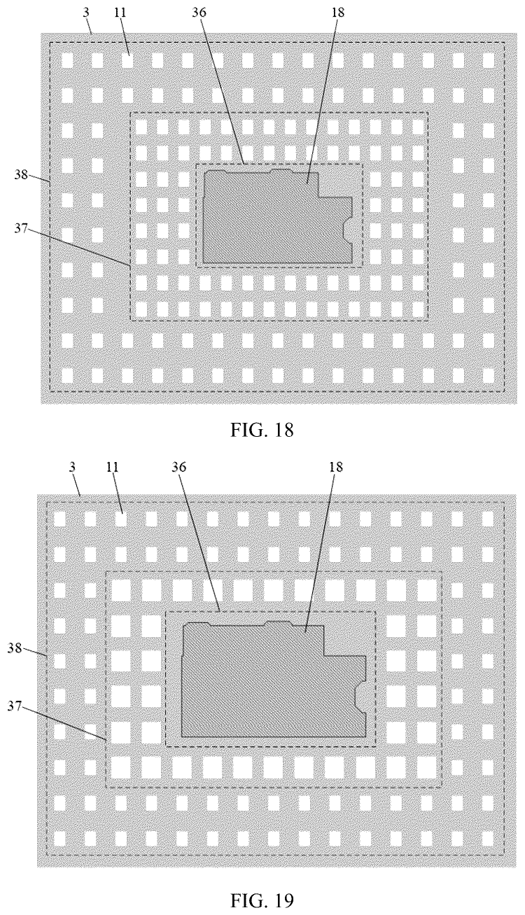

FIG. 18 is a schematic diagram of a distribution of first vent holes according to an embodiment of the present disclosure. FIG. 19 is a schematic diagram of another distribution of first vent holes according to an embodiment of the present disclosure. In a feasible implementation, as shown in FIG. 18 and FIG. 19, the display panel includes a first sub-region 36, a second sub-region 37 at least partially surrounding the first sub-region 36, and a third sub-region 38 at least partially surrounding the second sub-region 37.

The first sub-region 36 includes the first sub-portion 18. The first sub-region 36 may not include the first vent hole 11. Alternatively, the first sub-region 36 may include the first vent holes 11, but the distance between at least some of the first vent holes 11 in the first sub-region 36 is relatively large due to avoiding the first sub-portion 18, so that the distance between at least some of the first vent holes 11 in the first sub-region 36 is greater than the distance between the first vent holes 11 in the second sub-region 37 and greater than the distance between the first vent holes 11 in the third sub-region 38.

Referring to FIG. 18, in at least one same direction, the distance between at least some of the first vent holes 11 in the second sub-region 37 is less than the distance between at least some of the first vent holes 11 in the third sub-region 38. For example, FIG. 18 illustrates that in the first direction x, the distance between adjacent first vent holes 11 in the second sub-region 37 is less than the distance between adjacent first vent holes 11 in the third sub-region 38, and in the second direction y, the distance between adjacent first vent holes 11 in the second sub-region 37 is less than the distance between adjacent first vent holes 11 in the third sub-region 38.

Additionally/alternatively, referring to FIG. 19, an area of each first vent hole 11 in the second sub-region 37 is greater than an area of each first vent hole 11 in the third sub-region 38.

In the embodiments of the present disclosure, in order to avoid the first sub-portion 18, the number of the first vent holes 11 in the first sub-region 36 is very small or is zero. In view of this, the porosity in the peripheral region of the first sub-region 36 may be increased by increasing the arrangement density and/or the area of the first vent holes 11 in the second sub-region 37 around the first sub-region 36, so as to compensate for porosity lost in the first sub-region 36, so that a good venting effect can still be achieved in the entire region.

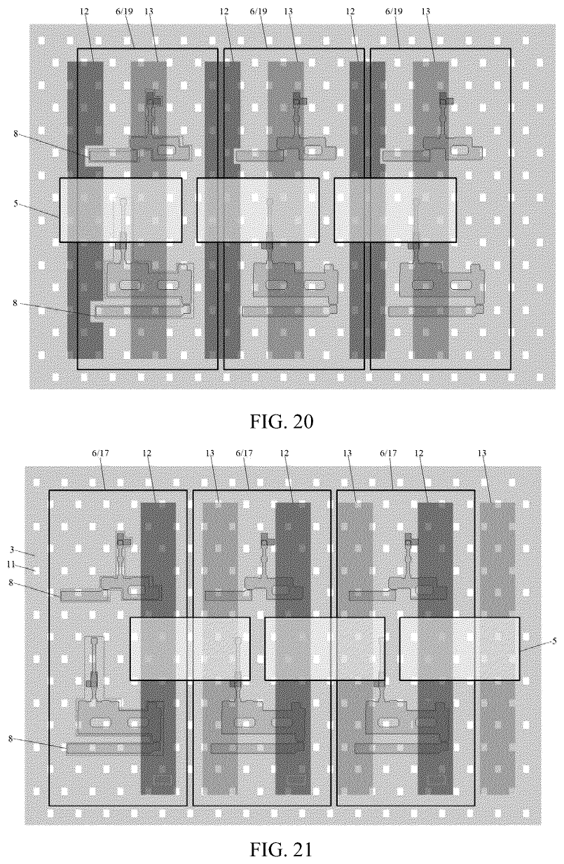

FIG. 20 is another schematic diagram of a display panel according to an embodiment of the present disclosure. In a feasible implementation, as shown in FIG. 20, in the direction perpendicular to the plane of the substrate 1, the second pixel circuit 19 overlaps with the first electrode 12, and in the second pixel circuit 19 and the first electrode 12 that overlap with each other, the first conductive portion 8 in the second pixel circuit 19 does not overlap with the first electrode 12.

In the embodiments of the present disclosure, the second pixel circuit 19 and the first electrode 12 overlapping therewith may have a connection relationship, or may not have a connection relationship.

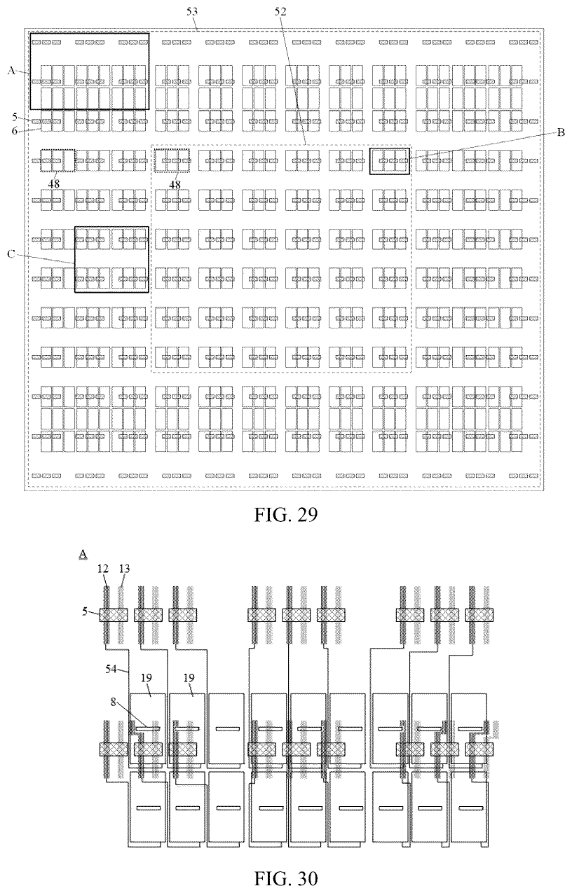

For example, with reference to FIG. 29 to FIG. 34, the display panel includes a first region 52 and a second region 53 at least partially surrounding the first region 52. The distance between at least one of the pixel circuits 6 in the second region 53 and respective light emitting element 5 connected to the respective pixel circuit 6 is greater than the distance between at least one of the pixel circuits 6 in the first region 52 and respective light emitting element 5 connected to the respective pixel circuit 6.

In the first region 52, the position of the pixel circuit 6 corresponds to the position of the light emitting element 5 connected thereto, that is, the pixel circuit 6 overlaps with the first electrode 12 connected thereto. When the first region 52 includes the second pixel circuit 19, the second pixel circuit 19 has a connection relationship with the first electrode 12 overlapping therewith.

In the second region 53, the position of some of the pixel circuits 6 corresponds to the position of the respective light emitting elements 5 connected thereto, and the position of some of the pixel circuits 6 does not correspond to the position of the respective light emitting elements 5 connected thereto. That is, some of the pixel circuits 6 overlap with the respective first electrodes 12 connected thereto, and some of the pixel circuits 6 do not overlap with the respective first electrodes 12 connected thereto. In other words, the pixel circuit 6 in the second region 53 may or may not have a connection relationship with the first electrode 12 overlapping therewith. Therefore, when the second region 53 includes the second pixel circuit 19, the second pixel circuit 19 may or may not have a connection relationship with the first electrode 12 overlapping therewith.

Referring to FIG. 20, the shape of the first electrode 12 overlapping with at least part of the second pixel circuits 19 may vary. Additionally/alternatively, FIG. 21 is another schematic diagram of a display panel according to an embodiment of the present disclosure. With reference to FIG. 20 and FIG. 21, the shape of the first electrode 12 overlapping with at least part of the second pixel circuits 19 is different from the shape of the first electrode 12 overlapping with at least part of the first pixel circuits 17.

In the second pixel circuit 19 and the first electrode 12 that overlap with each other, adjusting the shape of the first electrode 12 can make the first electrode 12 avoid the first conductive portion 8 in the second pixel circuit 19, thereby avoiding the influence of the anode signal on the first electrode 12 on the gate potential of the driving transistor 7.

In the second pixel circuits 19 and the first electrodes 12 that at least partially overlap with each other, the relative position relationship between the second pixel circuit 19 and the first electrode 12 may vary. Therefore, when adjusting the shape of the first electrode 12 to avoid the first conductive portion 8 in the second pixel circuit 19, the adjustment manner of the shape may vary. For example, as illustrated in FIG. 20, the size and number of notches in three first electrodes 12 may vary, so that the shapes of the first electrodes 12 overlapping with at least part of the second pixel circuits 19 are different.

Additionally/alternatively, comparing FIG. 20 and FIG. 21, since a manner of causing the first vent hole 11 to avoid the first sub-portion 18 may be adopted at a position of the first pixel circuit 17 to shield the coupling between the first electrode 12 and the first sub-portion 18, the shape of the first electrode 12 overlapping with the first pixel circuit 17 does not need to be adjusted. After the shape of the first electrode 12 overlapping with the second pixel circuit 19 is adjusted, the shape of the first electrode 12 overlapping with at least part of the second pixel circuits 19 is different from the shape of the first electrode 12 overlapping with at least part of the first pixel circuits 17. For example, as illustrated in FIG. 20 and FIG. 21, the first electrode 12 overlapping with the second pixel circuit 19 includes a notch, and the first electrode 12 overlapping with the first pixel circuit 17 does not include a notch.

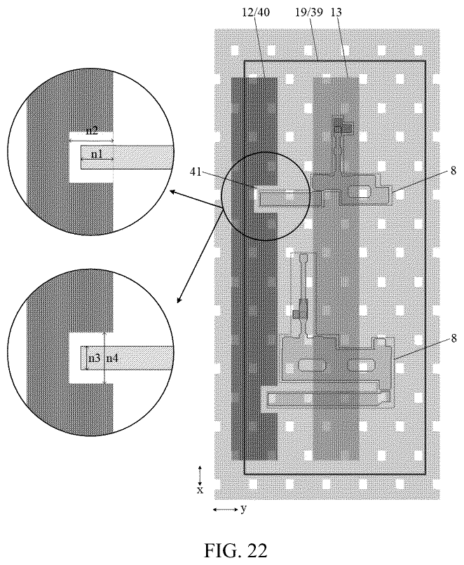

FIG. 22 is another schematic diagram of a display panel according to an embodiment of the present disclosure. In a feasible implementation, as shown in FIG. 22, the second pixel circuit 19 includes a first sub-circuit 39, and the first electrode 12 includes a first sub-electrode 40. In other words, some of the second pixel circuits 19 are the first sub-circuits 39, and some of the first electrodes 12 are the first sub-electrodes 40. In the direction perpendicular to the plane of the substrate 1, the first sub-circuit 39 overlaps with the first sub-electrode 40.

The first sub-electrode 40 includes a notch 41.

In the first sub-circuit 39 and the first sub-electrode 40 overlapping with each other, along a direction intersecting with the recessing direction of the notch 41, the orthographic projection of the first conductive portion 8 in the first sub-circuit 39 onto the plane of the substrate 1 overlaps with the orthographic projection of the notch 41 onto the plane of the substrate 1. In the structure shown in FIG. 22, along the first direction x, the orthographic projection of the first conductive portion 8 in the first sub-circuit 39 onto the plane of the substrate 1 overlaps with the orthographic projection of the notch 41 onto the plane of the substrate 1. Or it may be illustrated that the orthographic projection of an end of the first conductive portion 8 in the first sub-circuit 39 onto the plane of the substrate 1 is embedded within the orthographic projection of the notch 41 onto the plane of the substrate 1.

Further, the width of a portion where the first conductive portion 8 overlaps with the first sub-electrode 40 along the first direction x is n1, and the width of the notch 41 in the second direction y is n2, where n2>n1. The width of a portion where the first conductive portion 8 overlaps with the first sub-electrode 40 along the second direction y is n3, and the width of the notch 41 in the first direction x is n4, where n4>n3. In this way, a spacing is provided between the notch 41 and the end of the first conductive portion 8, so as to provide a margin for process accuracy.

When the first conductive portion 8 in the second pixel circuit 19 only overlaps with the first electrode 12 at the end position, the first conductive portion 8 is avoided by providing the notch 41 at the corresponding position of the first electrode 12, adjustment to the shape of the first electrode 12 is relatively small, and the binding of the light emitting element 5 is generally not affected while reducing or eliminating signal interference.

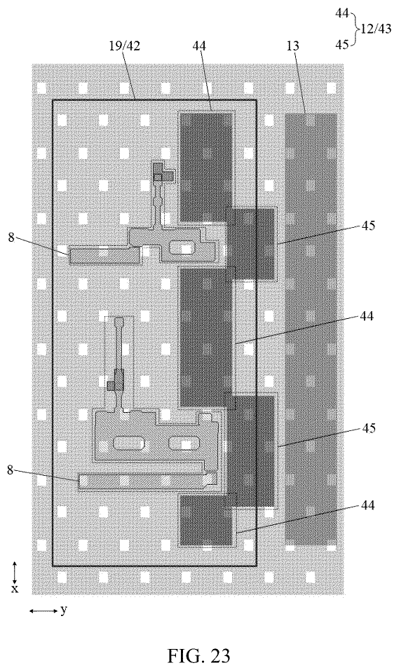

FIG. 23 is another schematic diagram of a display panel according to an embodiment of the present disclosure. In a feasible implementation, as shown in FIG. 23, the second pixel circuit 19 includes a second sub-circuit 42, and the first electrode 12 includes a second sub-electrode 43. In other words, some of the second pixel circuits 19 are the second sub-circuits 42, and some of the first electrodes 12 are the second sub-electrodes 43. In the direction perpendicular to the plane of the substrate 1, the second sub-circuit 42 overlaps with the second sub-electrode 43.

The second sub-electrode 43 includes a first sub-electrode portion 44 and a second sub-electrode portion 45.

In the second sub-circuit 42 and the second sub-electrode 43 overlapping with each other, the orthographic projection of the first conductive portion 8 in the second sub-circuit 42 onto the plane of the substrate 1 overlaps with the orthographic projection of the first sub-electrode portion 44 onto the plane of the substrate 1 in the first direction x, the orthographic projection of the first conductive portion 8 in the second sub-circuit 42 onto the plane of the substrate 1 overlaps with the orthographic projection of the second sub-electrode portion 45 onto the plane of the substrate 1 in the second direction y, and at least part of the first sub-electrode portion 44 does not overlap with the second sub-electrode portion 45 in the first direction x. The second direction y intersects with the first direction x.

In an embodiment, the second sub-electrode 43 avoids the first conductive portion 8 in the second sub-circuit 42 by partially bending. The second sub-electrode portion 45 in the second sub-electrode 43 is bent to a side of the first conductive portion 8 in the first direction x, so as to prevent the second sub-electrode 43 from overlapping with the first conductive portion 8 in the direction perpendicular to the plane of the substrate 1. After the second sub-electrode 43 is partially bent, the shape of the second electrode 13 on a side of the second sub-electrode 43 may also be adjusted to adapt to the shape of the second sub-electrode 43.

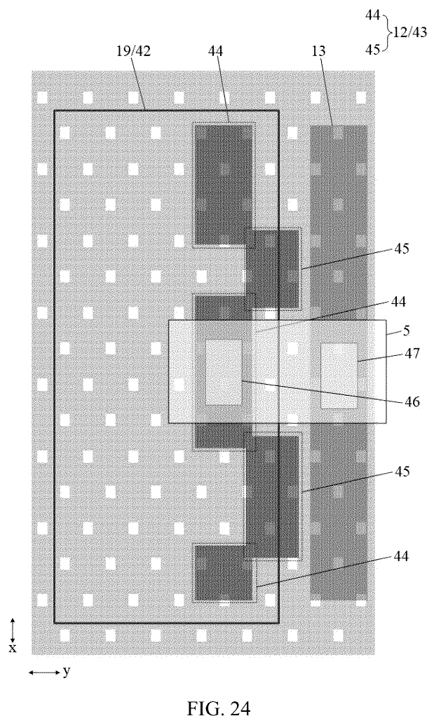

FIG. 24 is another schematic diagram of a display panel according to an embodiment of the present disclosure. Further, as shown in FIG. 24, the first direction x is the extending direction of the first electrode 12, and the extending direction refers to an extending direction of the first electrode 12 as a whole, for example, a longitudinal direction shown in FIG. 24.

The light emitting element 5 includes a first terminal 46 and a second terminal 47, and the first terminal 46 is electrically connected to the first electrode 12. In the direction perpendicular to the plane of the substrate 1, the first sub-electrode portion 44 in the second sub-electrode 43 overlaps with the first terminal 46 of the light emitting element 5.

In such shape adjustment, the second sub-electrode portion 45 is locally/partially bent to avoid the first conductive portion 8, and the position of the first sub-electrode portion 44 remains unchanged. By making the binding position of the first terminal in the light emitting element 5 correspond to the position of the first sub-electrode portion 44, the position of the light emitting element 5 can be prevented from being affected by the position adjustment of the second sub-electrode 43, which does not affect the transfer process of the light emitting element 5, and also does not affect the original spacing between the light emitting elements 5.

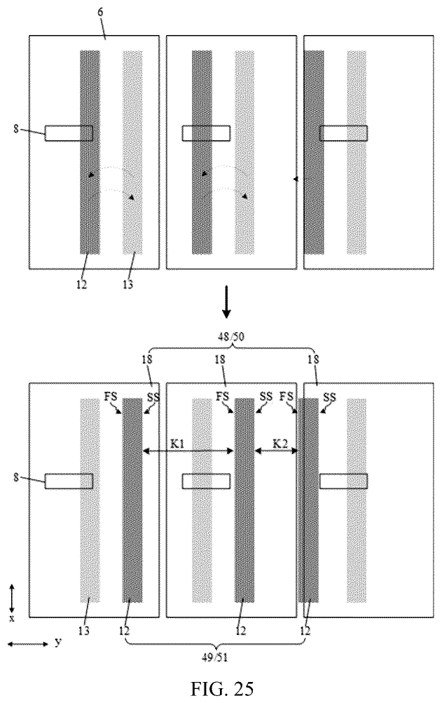

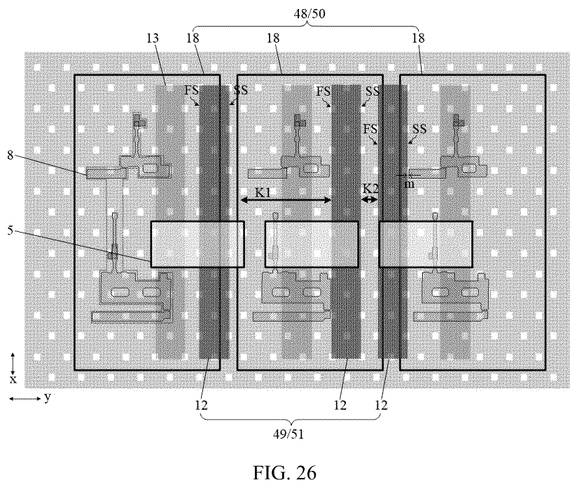

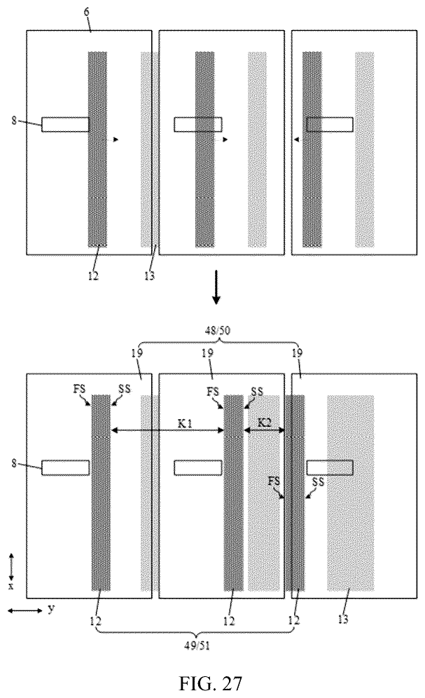

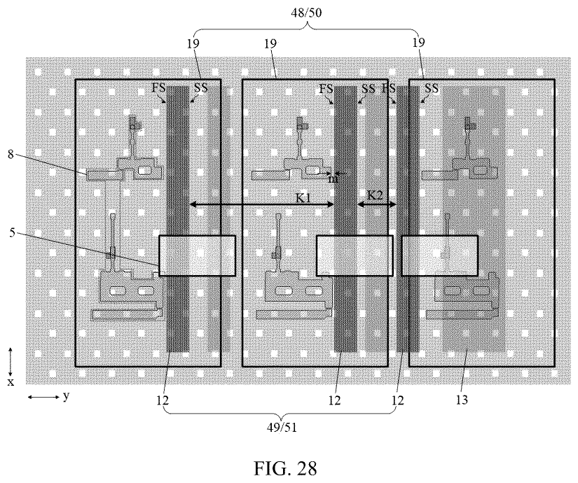

FIG. 25 is another schematic diagram of a display panel according to an embodiment of the present disclosure. FIG. 26 is another schematic diagram of a display panel according to an embodiment of the present disclosure. FIG. 27 is another schematic diagram of a display panel according to an embodiment of the present disclosure. FIG. 28 is another schematic diagram of a display panel according to an embodiment of the present disclosure. In a feasible implementation, with reference to FIG. 29 and as shown in FIG. 25 to FIG. 28, the circuit layer 2 includes circuit units 48, and the circuit units 48 include pixel circuits 6 arranged along the second direction y. The pixel circuits 6 in the circuit units 48 may be respectively electrically connected to light emitting elements 5 of different colors. For example, the circuit units 48 include three pixel circuits 6, and the three pixel circuits 6 are respectively electrically connected to red, green and blue light emitting elements 5.

The second metal portion 4 includes electrode units 49 corresponding to the circuit units 48, and the electrode units 49 include first electrodes 12 arranged along the second direction y. The first electrodes 12 in the electrode units 49 are correspondingly electrically connected to the pixel circuits 6 in the corresponding circuit units 48.

The circuit units 48 include a first circuit unit 50, the first circuit unit 50 includes the second pixel circuit 19, and the electrode unit 49 includes a first electrode unit 51. In the direction perpendicular to the plane of the substrate 1, the first circuit unit 50 overlaps with the first electrode unit 51, and the first conductive portion 8 in the first circuit unit 50 does not overlap with the first electrode 12 in the first electrode unit 51.

In an embodiment of the present disclosure, the first circuit unit 50 may or may not have a connection relationship with the first electrode unit 51 overlapping therewith.

For example, with reference to FIG. 29, the display panel includes a first region 52 and a second region 53 at least partially surrounding the first region 52. The distance between at least one of the pixel circuit 6 in the second region 53 and the respective light-emitting element 5 connected to the respective pixel circuit 6 is greater than the distance between at least one of the pixel circuits 6 in the first region 52 and the respective light emitting element 5 connected to the respective pixel circuit 6. In the first region 53, at least some of the pixel circuits 6 respectively overlap with the respective light emitting elements 5 connected thereto, that is, at least some of the pixel circuits 6 overlap with the respective first electrodes 12 connected thereto. At least some of the pixel circuits 6 do not overlap with the respective light emitting elements 5 connected thereto, that is, at least some of the pixel circuits 6 do not overlap with the respective first electrodes 12 connected thereto. When the first region 52 includes the second pixel circuit 19, the second pixel circuit 19 is electrically connected to the first electrode 12 overlapping therewith. When the second region 53 includes the second pixel circuits 19, at least part of the second pixel circuits 19 have no connection relationship with the first electrode 12 overlapping therewith.

For some first electrodes 12 in the first electrode units 51, a first distance K1 exists between adjacent first electrodes 12, and a second distance K2 exists between adjacent first electrodes 12, where the first distance K1 is different from the second distance K2.

In an embodiment, the first electrode 12 avoids the first conductive portion 8 in the second pixel circuit 19 by adjusting the position of the first electrode 12. In the second pixel circuit 19 and the first electrode 12 that overlap with each other, by adjusting the position of the first electrode 12 and causing the first electrode 12 to move in the second direction y, the first electrode 12 can avoid the first conductive portion 8 in the second pixel circuit 19, thereby avoiding the influence of the anode signal on the first electrode 12 on the gate potential of the driving transistor 7.

In a possible implementation, referring to FIG. 25 and FIG. 26, the first electrode 12 includes a first side FS and a second side SS opposite to each other in the second direction y.

In at least some of the first electrode units 51, the first side FS of at least one first electrode 12 includes a second electrode 13 connected to the same light emitting element 5 as the respective first electrode 12, and the second side SS of at least one first electrode 12 includes a second electrode 13 connected to the same light emitting element 5 as the respective first electrode 12. For example, in the structure illustrated in FIG. 26, the first side FS of each of the two first electrodes 12 on the left is provided with a second electrode 13 connected to the same light emitting element 5 as the respective first electrode 12, and the second side SS of the first electrode 12 on the right is provided with a second electrode 13 connected to the same light emitting element 5 as the first electrode 12 on the right.

In such an arrangement manner, in the first electrode units 51, some of the first electrodes 12 avoid the first conductive portion 8 by exchanging positions with the corresponding second electrodes 13. After the position of the first electrode 12 is exchanged with the position of the second electrode 13, the distance between the first electrode 12 and at least one first electrode 12 adjacent thereto is changed, so that different adjacent first electrodes 12 in the first electrode units 51 have the first distance K1 and the second distance K2.

In a feasible implementation, referring to FIG. 27 and FIG. 28, in at least some of the first electrode units 51, the distances between at least some of the first electrodes 12 and the second electrodes 13 connected to the same light emitting elements 5 as the respective first electrodes 12 are different. Further, the first electrode 12 includes a first side FS and a second side SS opposite to each other in the second direction y. In these first electrode units 51, the second side SS of the first electrode 12 includes a second electrode 13 connected to the same light emitting element 5 as the first electrode 12.

In such an arrangement manner, in at least some of the first electrode units 51, some of the first electrodes 12 do not exchange positions with the corresponding second electrodes 13, and only move in the second direction y, so as to avoid the first conductive portion 8. After such positional adjustment of the first electrodes 12, the distance between the first electrode 12 and at least one first electrode 12 adjacent thereto is changed, so that different adjacent first electrodes 12 in the first electrode units 51 have the first distance K1 and the second distance K2.

In a feasible implementation, referring to FIG. 26 and FIG. 28, when adjusting the shape or position of the first electrode 12 to avoid the first conductive portion 8, in the second pixel circuit 19 and the first electrode 12 overlapping with each other, the minimum distance m between the orthographic projection of the first conductive portion 8 in the second pixel circuit 19 onto the plane of the substrate 1 and the orthographic projection of the first electrode 12 onto the plane of the substrate 1 is greater than 5 μm, thereby providing a certain margin for positional deviation of the first electrode 12 and the first conductive portion 8, and ensuring that the two are staggered from each other even if the positional deviation occurs between the first electrode 12 and the first conductive portion 8 due to process accuracy or the like.

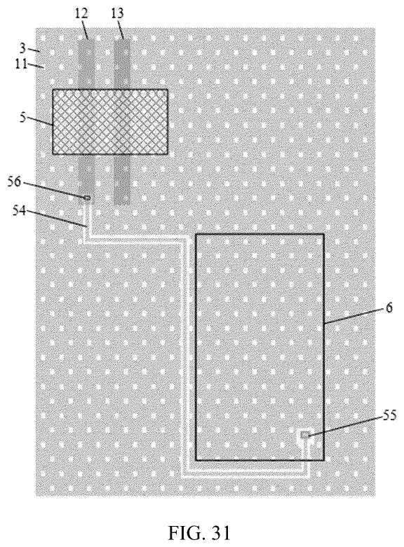

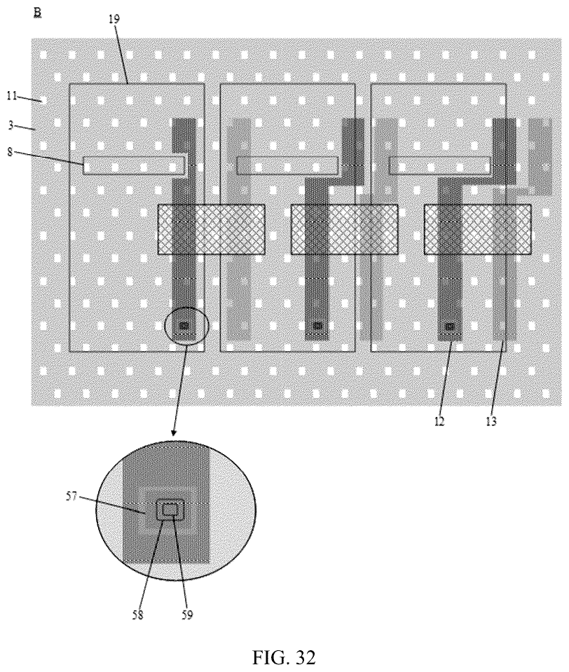

FIG. 29 is another schematic diagram of a display panel according to an embodiment of the present disclosure. FIG. 30 is a schematic diagram of a region A in FIG. 29. FIG. 31 is another schematic diagram of a display panel according to an embodiment of the present disclosure. FIG. 32 is a schematic diagram of a region B in FIG. 29. In a feasible implementation, as shown in FIG. 29 to FIG. 32, the display panel includes a first region 52 and a second region 53 at least partially surrounding the first region 52. The distance between at least one of the pixel circuits 6 in the second region 53 and the respective light emitting element 5 connected to the respective pixel circuit 6 is greater than the distance between at least one of the pixel circuits 6 in the first region 52 and the respective light emitting element 5 connected to the respective pixel circuit 6.

In such a panel structure, the second region 53 is close to the edge of the display panel. In the second region 53, the spacing between at least some of the pixel circuits 6 is compressed. For example, along the first direction x, the distance between at least some of the circuit units 48 in the second region 53 is less than the distance between the circuit units 48 in the first region 52. Along the second direction y, the distance between at least some of the circuit units 48 in the second region 53 is less than the distance between the circuit units 48 in the first region 52. As a result, the distance between at least one of the pixel circuits 6 and the corresponding light emitting element 5 is increased, that is, the distance between at least one of the pixel circuits 6 and the respective first electrode 12 connected thereto is increased.

Exemplarily, in the first region 52, the distance between at least one of the pixel circuits 6 and the respective light emitting element 5 connected thereto is zero, that is, at least one of the pixel circuits 6 overlaps with the respective light emitting element 5 connected thereto. In the second region 53, the distance between at least one of the pixel circuits 6 and the respective light emitting element 5 connected thereto is greater than zero. Referring to FIG. 30 and FIG. 31, the pixel circuit 6 is respectively connected to the respective first electrode 12 connected thereto through a first connection line 54. The first connection line 54 may be arranged in the same layer as the first metal portion 3, and a spacing is formed between the first connection line 54 and the first metal portion 3. The pixel circuit 6 is connected to the first connection line 54 through a first via hole 55, and the first connection line 54 is electrically connected to the first electrode 12 through a second via hole 56.

In the first region 52, referring to FIG. 32, at least one of the pixel circuits 6 overlaps with the respective light emitting element 5 connected thereto, and the pixel circuit 6 is electrically connected to the first electrode 12 connected thereto through the first connection portion 57. The first connection portion 57 may be arranged in the same layer as the first metal portion 3, and the spacing is formed between the first connection portion 57 and the first metal portion 3. The pixel circuit 6 is connected to the first connection portion 57 through a third via hole 58, and the first connection portion 57 is electrically connected to the first electrode 12 through a fourth via hole 59.

Such a panel structure can realize an ultra-narrow bezel or even a borderless panel, and is more suitable for application in a spliced display device, which can effectively eliminate splicing gaps.

Referring to FIG. 32, the first region 52 includes a second pixel circuit 19. In the first region 52, the first conductive portion 8 in the second pixel circuit 19 at least does not overlap with the first electrode 12 connected to the second pixel circuit 19.

The first region 52 is a conventional display region, and the pixel circuit 6 in the first region 52 overlaps with the first electrode 12 connected thereto. In an embodiment of the present disclosure, by adjusting the shapes or the positions of the first electrodes 12 connected to at least some of the pixel circuits 6 (the second pixel circuits 19) in the first region 52, the first conductive portions 8 in these pixel circuits 6 are staggered from the first electrodes 12, which can prevent the anode signal from affecting the gate potential of the driving transistors 7 in these pixel circuits 6.

With reference to FIG. 29 to FIG. 31, in a feasible implementation, the display panel includes a first region 52 and a second region 53 at least partially surrounding the first region 52. The distance between at least one of the pixel circuits 6 in the second region 53 and the respective light emitting element 5 connected to the respective pixel circuit 6 is greater than the distance between at least one of the pixel circuits 6 in the first region 52 and the respective light emitting element 5 connected to the respective pixel circuit 6.

The first region 52 and the second region 53 have been described in the above embodiments, which will not be repeated herein.

The second region 53 includes a second pixel circuit 19. In the second region 53, the first conductive portion 8 in the second pixel circuit 19 does not overlap with the first electrode 12 connected to the second pixel circuit 19, and also does not overlap with the first electrode 12 connected to other pixel circuit 6 in the second region 53.

In the second region 53, at least some of the pixel circuits 6 do not overlap with the respective first electrodes 12 connected thereto, but overlap with the respective first electrodes 12 connected to other pixel circuits 6. In an embodiment of the present disclosure, by adjusting the shapes or positions of the first electrodes 12 overlapping with at least some of the pixel circuits 6 (the second pixel circuits 19), the first conductive portions 8 in these pixel circuits 6 are staggered from the first electrodes 12, which can prevent the anode signals from affecting the gate potentials of the first driving transistors in these pixel circuits 6.

In the original design, in the second region 53, the overlapping positions of different pixel circuits 6 and the respective first electrodes 12 thereabove may be different, so that the overlapping situations between the first conductive portions 8 and the first electrodes 12 in different pixel circuits 6 are different. In an embodiment of the present disclosure, the first electrodes 12 may be selectively adjusted in terms of the shapes or the positions according to the specific overlapping situations. For example, at some positions, when the first electrode 12 only overlaps with the end of the first conductive portion 8 to a small extent, the first electrode 12 may be selectively adjusted in position along the second direction y or a notch 41 may be provided at a position corresponding to the first electrode 12. At some other positions, when the first electrode 12 overlaps with the middle portion of the first conductive portion 8, the position of the first electrode 12 and the position of an adjacent second electrode 13 are exchanged, or the first electrode 12 may be adjusted in terms of the shape, to include the first sub-electrode portion 44 and the second sub-electrode portion 45.

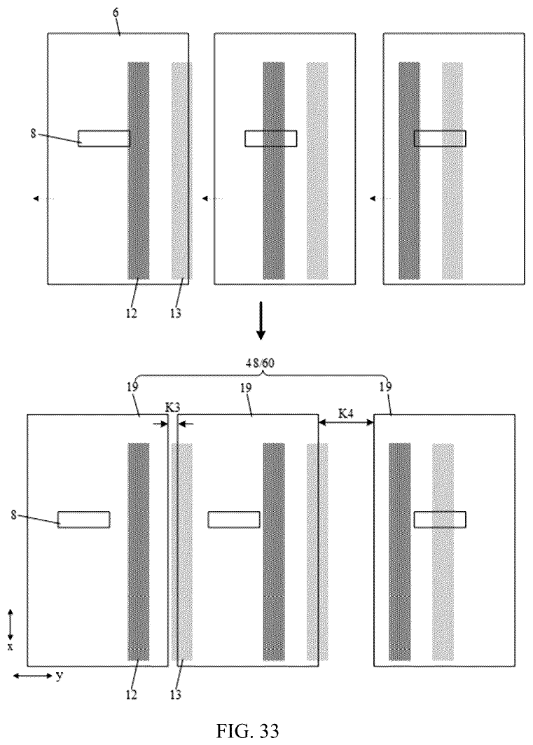

FIG. 33 is another schematic diagram of a display panel according to an embodiment of the present disclosure. In a feasible implementation, as shown in FIG. 33, the circuit layer 2 includes circuit units 48, and the circuit units 48 include pixel circuits 6 arranged along the second direction y. The pixel circuits 6 in the circuit units 48 may be respectively electrically connected to light emitting elements 5 of different colors. For example, the circuit units 48 include three pixel circuits 6, and the three pixel circuits 6 are respectively electrically connected to red, green and blue light emitting elements 5.

The circuit unit 48 includes a second circuit unit 60 including the second pixel circuit 19.

In the second circuit unit 60, the third distance K3 exists between at least some of adjacent pixel circuits 6, and the fourth distance K4 exists between at least one second pixel circuit 19 and another pixel circuit 6 adjacent thereto. The fourth distance K4 is different from the third distance K3.

In the conventional circuit unit 48, the distances between adjacent pixel circuits 6 are equal. The above arrangement manner causes the first conductive portion 8 to avoid the first electrode 12 above by adjusting the positions of at least some of the pixel circuits 6 in the second circuit unit 60, and this manner can also reduce or eliminate the influence of the anode signal on the gate potential of the driving transistor 7 in the pixel circuit 6.

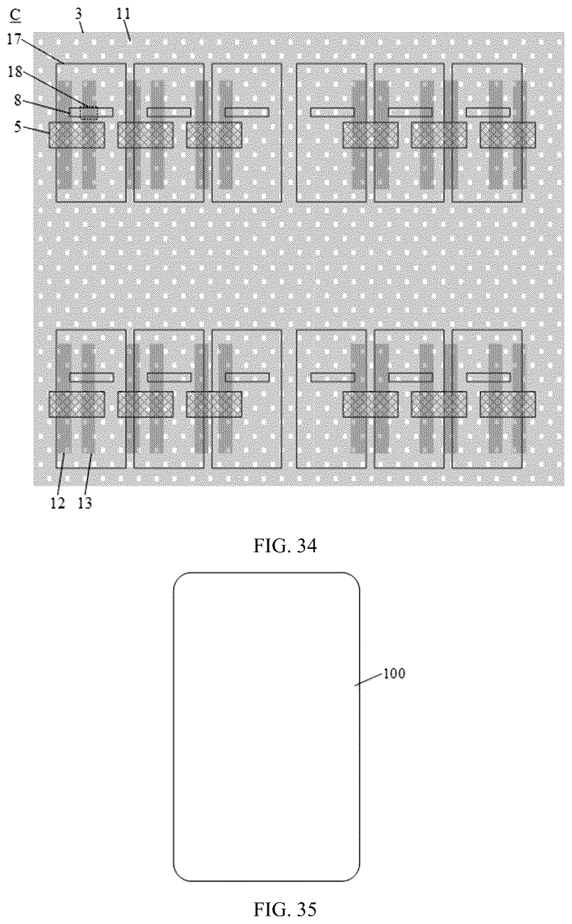

FIG. 34 is a schematic diagram of a region C in FIG. 29. In a feasible implementation, with reference to FIG. 29, FIG. 32, and FIG. 34, the display panel includes a first region 52 and a second region 53 at least partially surrounding the first region 52. The distance between at least one of the pixel circuits 6 in the second region 53 and respective light emitting element 5 connected to the respective pixel circuit 6 is greater than the distance between at least one of the pixel circuits 6 in the first region 52 and respective light emitting element 5 connected to the respective pixel circuit 6.

The first region 52 and the second region 53 have been described in the above-mentioned embodiments, which will not be repeated herein.

Referring to FIG. 34, the second region 53 at least includes the first pixel circuit 17, and/or referring to FIG. 32, the first region 52 at least includes the second pixel circuit 19.

In the second region 53, the overlapping situations between the pixel circuits 6 at different positions and the first electrodes 12 are different. At this time, the influence of the anode signals on the gate potentials of the driving transistors 7 in these pixel circuits 6 can be reduced or eliminated by enabling the positions of the first vent holes 11 in the first metal portions 3 to avoid the first conductive portions 8. Compared with adjusting the shapes or positions of the first electrodes 12, this manner is simpler. Further, compared with the first region 52, an area of the second region 53 is generally smaller. Even if some of the first vent holes 11 are removed in the second region 53, the overall aperture ratio is not greatly affected.

In the first region 52, the overlapping relationships between the pixel circuits 6 at different positions and the first electrodes 12 are relatively uniform. At this time, the first conductive portion 8 may be avoided by adjusting the shape or position of the first electrode 12, thereby reducing or eliminating the influence of the anode signal on the gate potential of the driving transistor 7 in these pixel circuits 6. Further, the first vent holes 11 in the first region 52 may not be removed, which can ensure that the first region 52 has a relatively high aperture ratio and optimize the venting effect in the first region 52.

It is understandable that, in other optional embodiments, the second region 53 may also include the second pixel circuit 19, and/or the first region 52 may also include the first pixel circuit 17.

In an embodiment of the present disclosure, the first region 52 includes the first pixel circuit 17 and/or the second pixel circuit 19, and the second region 53 includes the first pixel circuit 17 and/or the second pixel circuit 19, which can further improve the coupling consistency between the first conductive portion 8 and the first electrode 12 in the first region 52 and the second region 53, thereby improving the display uniformity of the first region 52 and the second region 53.

In a feasible implementation, among the pixel circuits 6 connected to the light emitting elements 5 of the same color, at least some of the pixel circuits 6 are the first pixel circuits 17, and/or at least some of the pixel circuits 6 are the second pixel circuits 19.

For example, the pixel circuit 6 connected to the red light emitting element 5 includes the first pixel circuit 17 and/or the second pixel circuit 19. The pixel circuit 6 connected to the green light emitting element 5 includes the first pixel circuit 17 and/or the second pixel circuit 19. The pixel circuit 6 connected to the blue light emitting element 5 includes the first pixel circuit 17 and/or the second pixel circuit 19.

In this way, the coupling between the gate of the driving transistor 7 and the first electrode 12 in the pixel circuit 6 connected to the light emitting element 5 of a same color is similar, and the consistency of the gate potential of the driving transistor 7 is better, which helps to improve the display uniformity of the light emitting element 5 of a same color.

In a feasible implementation, with reference to FIG. 29 and FIG. 30, the display panel includes a first region 52 and a second region 53 at least partially surrounding the first region 52. The distance between at least one of the pixel circuits 6 in the second region 53 and respective light emitting element 5 connected to the respective pixel circuit 6 is greater than the distance between at least one of the pixel circuits 6 in the first region 52 and respective light emitting element 5 connected to the respective pixel circuit 6.

The display panel further includes a first connection line 54. The first connection line 54 is arranged in the same layer as and spaced from the first metal portion 3. The first connection line 54 is respectively electrically connected to the first electrode 12 and the pixel circuit 6 in the second region 53. The first conductive portion 8 does not overlap with the first connection line 54 in the direction perpendicular to the plane of the substrate 1.

In the second region 53, the positions between at least some of the pixel circuits 6 and the respective light emitting elements 5 connected thereto are staggered from each other, so that the first connection line 54 needs to be used for connection. The first connection line 54 is connected to the first electrode 12, so that an anode signal is also transmitted on the first connection line 54. When configuring the first connection line 54, the extending position of the first connection line 54 can avoid the first conductive portion 8, so that the first connection line 54 and the first conductive portion 8 do not overlap with each other, thereby preventing the anode signal on the first connection line 54 from affecting the potential on the first conductive portion 8.

In a feasible implementation, the display panel further includes a first signal line, and the first signal line is electrically connected to the pixel circuit 6 and transmits a non-constant voltage signal. With reference to FIG. 11, the first signal line may include a swept-frequency signal line SWEEP, and/or the first signal line may include a connection line connected between devices and configured to transmit the non-constant voltage signal, and/or the first signal line may include a scan line located at a layer different from the metal layer of the first conductive portion 8.

In a direction perpendicular to a plane of the display panel, the first conductive portion 8 in the pixel circuit 6 does not overlap with the first signal line electrically connected to the pixel circuit 6, which can further reduce or eliminate the interference of voltage jump on these signal lines to the potential on the first conductive portion 8.

In a possible implementation, with reference to FIG. 10 and FIG. 11, the pixel circuit 6 includes a pulse amplitude modulation circuit 31 and a pulse width modulation circuit 32. The pulse amplitude modulation circuit 31 is configured to control the amplitude of the driving current based on the applied pulse amplitude modulation data, and the pulse width modulation circuit 32 is configured to control the pulse width of the driving current.

The pulse amplitude modulation circuit 31 includes a first driving transistor T3, and the pulse width modulation circuit 32 includes a second driving transistor T13. The driving transistor 7 includes a first driving transistor T3 and/or a second driving transistor T13.

Based on the technical solution according to the embodiments of the present disclosure, the interference of the anode signal on the gate potential of the first driving transistor T3 and/or the second driving transistor T13 can be reduced or eliminated, thereby improving the operational stability of the pulse amplitude modulation circuit 31 and the pulse width modulation circuit 32, and improving the accuracy of the driving current transmitted by the pixel circuit 6.

In a feasible implementation, with reference to FIG. 10 and FIG. 11, the pulse amplitude modulation circuit 31 further includes a second transistor receiving a first power signal PAM_VDD. For example, the second transistor includes a first light emitting control transistor M1 and a first control transistor M8. The pulse width modulation circuit 32 further includes a third transistor receiving a second power signal PWM_VDD. For example, the third transistor includes a second control transistor M9 and a third control transistor M10.

At least part of the first metal portion 3 transmits the first power signal PAM_VDD and is electrically connected to the second transistor, and/or at least part of the first metal portion 3 transmits the second power signal PWM_VDD and is electrically connected to the third transistor.

Both the first power signal PAM_VDD and the second power signal PWM_VDD are constant voltage signals. When the first metal portion 3 transmits the first power signal PAM_VDD or the second power signal PWM_VDD, the metal thereof is spaced between the first sub-portion 18 and the first electrode 12, and can provide a good shielding effect, effectively reducing the interference of the anode signal with the gate potential of the first driving transistor T3 and/or the second driving transistor T13.

In an example, the first metal portion 3 is configured to transmit the first power signal PAM_VDD, and the third transistor is electrically connected to the second power line PWM_VDD.

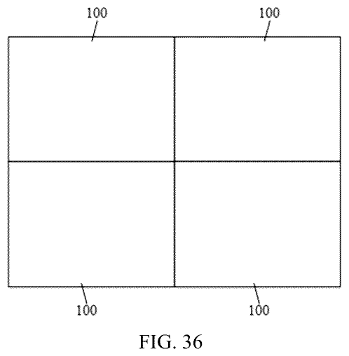

Based on a same inventive concept, an embodiment of the present disclosure further provides a display device. FIG. 35 is a schematic diagram of a display device according to an embodiment of the present disclosure. FIG. 36 is another schematic diagram of a display device according to an embodiment of the present disclosure. As shown in FIG. 35 and FIG. 36, the display device includes the display panel 100 described above.

In an embodiment of the present disclosure, the display device may be a mobile phone shown in FIG. 35, or an electronic device such as a tablet computer, a notebook computer, an electronic paper book, or a television, or may also be an electronic device such as a spliced large screen shown in FIG. 36. Among such electronic devices, the display device includes at least two display panels.

The above description merely illustrates some preferred embodiments of the present disclosure and is not intended to limit the present disclosure, and any modification, equivalent substitution, improvement and the like made within a spirit and a principle of the present disclosure shall fall with a scope of the present disclosure.

As above, it should be noted that, the above-described embodiments are merely for illustrating the present disclosure but not intended to provide any limitation. Although the present disclosure has been described in detail with reference to the above-described embodiments, it should be understood that those skilled in the art may also modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, comprising:
a substrate;
a circuit layer located on a side of the substrate, wherein the circuit layer comprises pixel circuits comprising a first pixel circuit and a second pixel circuit, one pixel circuit of the pixel circuits comprises a driving transistor and a first conductive portion; the first conductive portion comprises a first portion, and the first portion is a gate of the driving transistor; and/or the first conductive portion comprises a second portion, and the second portion is electrically connected to the gate of the driving transistor;
a first metal portion located on a side of the circuit layer away from the substrate, wherein the first metal portion comprises first vent holes;
a second metal portion located on a side of the first metal portion away from the substrate, wherein the second metal portion comprises a first electrode and a second electrode, and the first electrode is electrically connected to the pixel circuit; and
a light emitting element located on a side of the second metal portion away from the substrate, wherein the light emitting element is electrically connected to the first electrode and the second electrode,
wherein in the first pixel circuit, the first conductive portion comprises a first sub-portion; and in a direction perpendicular to a plane of the substrate, the first sub-portion overlaps with the first electrode, and the first sub-portion overlaps with the first metal portion and does not overlap with the first vent holes, and/or
in the direction perpendicular to the plane of the substrate, the first conductive portion in the second pixel circuit does not overlap with the first electrode.

2. The display panel according to claim 1, wherein
the pixel circuit further comprises a preset module electrically connected to the gate of the driving transistor, and the second portion is further electrically connected to the preset module.

3. The display panel according to claim 2, wherein
the preset module comprises a first capacitor, the first capacitor comprises a first electrode plate and a second electrode plate, and the first electrode plate is electrically connected to the gate of the driving transistor; and the second portion comprises a first wiring connected between the gate of the driving transistor and the first electrode plate; and/or
the preset module comprises a first capacitor, the first capacitor comprises a first electrode plate and a second electrode plate, and the first electrode plate is electrically connected to the gate of the driving transistor; and the second portion comprises an auxiliary electrode plate located on a side of the first capacitor away from the substrate, and in the direction perpendicular to the plane of the substrate, the auxiliary electrode plate overlaps with the first capacitor, and is electrically connected to the first electrode plate; and/or
the preset module comprises a first transistor electrically connected to the gate of the driving transistor; and the second portion comprises a second wiring connected between the gate of the driving transistor and the first transistor.

4. The display panel according to claim 1, wherein
the first vent holes comprise a first hole, a second hole and a third hole that are arranged in a same direction and adjacent to one another; and in the direction perpendicular to the plane of the substrate, the first hole, the second hole and the third hole overlap with a same first pixel circuit;
in the direction perpendicular to the plane of the substrate, the first metal portion between the second hole and the third hole overlaps with the first sub-portion, and a minimum distance between the second hole and the third hole is greater than a minimum distance between the second hole and the first hole.

5. The display panel according to claim 4, wherein
a length of the first sub-portion in an arrangement direction of the second hole and the third hole is d1, and a minimum distance between the second hole and the third hole is d2, where d2≥d1.

6. The display panel according to claim 1, further comprising: a first sub-region, a second sub-region at least partially surrounding the first sub-region, and a third sub-region at least partially surrounding the second sub-region, wherein
the first sub-region comprises the first sub-portion, and
in at least one same direction, a distance between two adjacent first vent holes in the second sub-region is less than a distance between two adjacent first vent holes in the third sub-region, and/or an area of one of the first vent holes in the second sub-region is greater than an area of one of the first vent holes in the third sub-region.

7. The display panel according to claim 1, wherein
in the direction perpendicular to the plane of the substrate, the second pixel circuit overlaps with the first electrode; and in the second pixel circuit and the first electrode that overlap with each other, the first conductive portion in the second pixel circuit does not overlap with the first electrode,
the first electrodes overlapping with at least part of the second pixel circuits have different shapes, and/or the first electrode overlapping with at least one of the second pixel circuits and the first electrode overlapping with at least one of the first pixel circuits have different shapes.

8. The display panel according to claim 7, wherein
the second pixel circuit comprises a first sub-circuit, the first electrode comprises a first sub-electrode, and in the direction perpendicular to the plane of the substrate, the first sub-circuit overlaps with the first sub-electrode; and
the first sub-electrode comprises a notch, and in the first sub-circuit and the first sub-electrode that overlap with each other, along a direction intersecting with a recessing direction of the notch, an orthographic projection of the first conductive portion in the first sub-circuit onto the plane of the substrate overlaps with an orthographic projection of the notch onto the plane of the substrate.

9. The display panel according to claim 7, wherein
the second pixel circuit comprises a second sub-circuit, the first electrode comprises a second sub-electrode, and in the direction perpendicular to the plane of the substrate, the second sub-circuit overlaps with the second sub-electrode; and
the second sub-electrode comprises a first sub-electrode portion and a second sub-electrode portion; in the second sub-circuit and the second sub-electrode that overlap with each other, an orthographic projection of the first conductive portion in the second sub-circuit onto the plane of the substrate overlaps with an orthographic projection of the first sub-electrode portion onto the plane of the substrate in a first direction, the orthographic projection of the first conductive portion in the second sub-circuit onto the plane of the substrate overlaps with an orthographic projection of the second sub-electrode portion onto the plane of the substrate in a second direction, at least part of the first sub-electrode portion does not overlap with the second sub-electrode portion in the first direction, and the second direction intersects with the first direction.

10. The display panel according to claim 9, wherein
the first direction is an extending direction of the first electrode;
the light emitting element comprises a first terminal and a second terminal, and the first terminal is electrically connected to the first electrode; and
in the direction perpendicular to the plane of the substrate, the first sub-electrode portion in the second sub-electrode overlaps with the first terminal of the light emitting element.

11. The display panel according to claim 1, wherein
the circuit layer comprises circuit units comprising the pixel circuits arranged along a second direction;
the second metal portion comprises electrode units corresponding to the circuit units, the electrode units comprise the first electrodes arranged along the second direction, and the first electrodes in the electrode units are correspondingly electrically connected to the pixel circuits in the circuit units,
the circuit units comprise a first circuit unit, the first circuit unit comprises the second pixel circuit, and the electrode units comprise a first electrode unit; and in the direction perpendicular to the plane of the substrate, the first circuit unit overlaps with the first electrode unit, and the first conductive portion in the first circuit unit does not overlap with the first electrode in the first electrode unit; and
a first distance exists between adjacent first electrodes in the first electrode units, a second distance exists between adjacent first electrodes, and the first distance is different from the second distance.

12. The display panel according to claim 7, wherein
in the second pixel circuit and the first electrode that overlap with each other, a minimum distance between an orthographic projection of the first conductive portion in the second pixel circuit onto the plane of the substrate and an orthographic projection of the first electrode onto the plane of the substrate is greater than 5 μm.

13. The display panel according to claim 1, further comprising a first region and a second region at least partially surrounding the first region, wherein
a distance between one of at least one of the pixel circuits in the second region and a respective one of the light emitting elements connected thereto is greater than a distance between one of at least one of the pixel circuits in the first region and a respective one of the light emitting elements connected thereto, and
the first region comprises the second pixel circuit, and in the first region, the first conductive portion in the second pixel circuit at least does not overlap with the first electrode connected to the second pixel circuit; or the second region comprises the second pixel circuit, and in the second region, the first conductive portion in the second pixel circuit does not overlap with the first electrode connected to the second pixel circuit, and also does not overlap with the first electrodes connected to other pixel circuits in the second region.

14. The display panel according to claim 1, wherein
the circuit layer comprises circuit units, the circuit units comprise the pixel circuits arranged along a second direction, and the pixel circuits in the circuit units are respectively electrically connected to the light emitting elements of different colors;
the circuit units comprise a second circuit unit comprising the second pixel circuit; and
in the second circuit unit, a third distance exists between adjacent pixel circuits, a fourth distance exists between one of the second pixel circuits and another one of the pixel circuits adjacent thereto, and the fourth distance is different from the third distance.

15. The display panel according to claim 1, further comprising a first region and a second region at least partially surrounding the first region, wherein
a distance between one of at least one of the pixel circuits in the second region and a respective one of the light emitting elements connected thereto is greater than a distance between one of at least one of the pixel circuits in the first region and a respective one of the light emitting elements connected thereto, and
the second region at least comprises the first pixel circuit, and/or the first region at least comprises the second pixel circuit.

16. The display panel according to claim 1, further comprising a first region and a second region at least partially surrounding the first region, wherein
a distance between one of at least one of the pixel circuits in the second region and a respective one of the light emitting elements connected thereto is greater than a distance between one of at least one of the pixel circuits in the first region and a respective one of the light emitting elements connected thereto; and
the display panel further comprises a first connection line located in the same layer as the first metal portion and spaced from the first metal portion, the first connection line is respectively electrically connected to the first electrode and the pixel circuit in the second region, and the first conductive portion does not overlap with the first connection line in the direction perpendicular to the plane of the substrate.

17. The display panel according to claim 1, further comprising:
a first signal line electrically connected to the pixel circuit and transmitting a non-constant voltage signal,
wherein in a direction perpendicular to a plane of the display panel, the first conductive portion in the pixel circuit does not overlap with the first signal line electrically connected to the pixel circuit.

18. The display panel according to claim 1, wherein
the pixel circuit comprises a pulse amplitude modulation circuit and a pulse width modulation circuit, the pulse amplitude modulation circuit comprises a first driving transistor, and the pulse width modulation circuit comprises a second driving transistor; and
the driving transistor comprises the first driving transistor and/or the second driving transistor.

19. The display panel according to claim 18, wherein
the pulse amplitude modulation circuit further comprises a second transistor configured to receive a first power signal, and the pulse width modulation circuit further comprises a third transistor configured to receive a second power signal; and
at least part of the first metal portion transmits the first power signal and is electrically connected to the second transistor, and/or at least part of the first metal portion transmits the second power signal and is electrically connected to the third transistor.

20. A display device, comprising a display panel comprising:
a substrate;
a circuit layer located on a side of the substrate, wherein the circuit layer comprises pixel circuits comprising a first pixel circuit and a second pixel circuit, one pixel circuit of the pixel circuits comprises a driving transistor and a first conductive portion; the first conductive portion comprises a first portion, and the first portion is a gate of the driving transistor; and/or the first conductive portion comprises a second portion, and the second portion is electrically connected to the gate of the driving transistor;
a first metal portion located on a side of the circuit layer away from the substrate, wherein the first metal portion comprises first vent holes;
a second metal portion located on a side of the first metal portion away from the substrate, wherein the second metal portion comprises a first electrode and a second electrode, and the first electrode is electrically connected to the pixel circuit; and
a light emitting element located on a side of the second metal portion away from the substrate, wherein the light emitting element is electrically connected to the first electrode and the second electrode,
wherein in the first pixel circuit, the first conductive portion comprises a first sub-portion; and in a direction perpendicular to a plane of the substrate, the first sub-portion overlaps with the first electrode, and the first sub-portion overlaps with the first metal portion and does not overlap with the first vent holes, and/or
in the direction perpendicular to the plane of the substrate, the first conductive portion in the second pixel circuit does not overlap with the first electrode.
